(19) United States
(12) Patent Application Publication
(10) Pub. No.: US 2026/0006858 A1
(43) Pub. Date: Jan. 1, 2026

(54) SEMICONDUCTOR DEVICE WITH PROGRAMMABLE STRUCTURE AND METHOD FOR FABRICATING THE SAME

(71) Applicant: NANYA TECHNOLOGY CORPORATION, NEW TAIPEI CITY (TW)

(72) Inventor: PING HSU, NEW TAIPEI CITY (TW)

(21) Appl. No.: 18/766,968

(22) Filed: Jul. 9, 2024

Related U.S. Application Data
(62) Division of application No. 18/755,963, filed on Jun. 27, 2024.

(51) Int. Cl. H01L 29/78; H01L 29/04; H01L 29/423; H01L 29/66

(52) U.S. Cl. CPC H10D 30/711; H10D 62/405; H10D 64/021; H10D 64/514

(57) ABSTRACT

The present application discloses a semiconductor device and a method for fabricating the semiconductor device. The semiconductor device includes a substrate; a peripheral impurity region positioned in the substrate; a top electrode layer positioned in the peripheral impurity region and protruding upwardly from the substrate; and a middle insulating layer inwardly positioned in the peripheral impurity region and partially surrounding the top electrode layer to separate the peripheral impurity region and the top electrode layer. The peripheral impurity region, the middle insulating layer, and the top electrode layer together configure a programmable structure.

### CROSS-REFERENCE TO RELATED APPLICATION

This application is a divisional application of U.S. Non-Provisional application Ser. No. 18/755,963 filed Jun. 27, 2024, which is incorporated herein by reference in its entirety.

### TECHNICAL FIELD

The present disclosure relates to a semiconductor device and a method for fabricating the semiconductor device, and more particularly, to a semiconductor device with a programmable structure and a method for fabricating the semiconductor device with the programmable structure.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device including a substrate; a peripheral impurity region positioned in the substrate; a top electrode layer positioned in the peripheral impurity region and protruding upwardly from the substrate; and a middle insulating layer inwardly positioned in the peripheral impurity region and partially surrounding the top electrode layer to separate the peripheral impurity region and the top electrode layer. The peripheral impurity region, the middle insulating layer, and the top electrode layer together configure a programmable structure.

Another aspect of the present disclosure provides a semiconductor device including a substrate; a peripheral impurity region positioned in the substrate; a middle insulating layer including a bottom tip portion positioned within the peripheral impurity region, and a top portion positioned on the bottom tip portion and above the substrate; and a top electrode layer positioned on the top portion of the middle insulating layer. The peripheral impurity region, the middle insulating layer, and the top electrode layer together configure a programmable structure.

Another aspect of the present disclosure provides a method for fabricating a semiconductor device including providing a substrate and forming a peripheral impurity region in the substrate; forming a first inter-dielectric layer on the substrate; forming a recess penetrating the first inter-dielectric layer and extending to the peripheral impurity region; forming a middle insulating layer on the first inter-dielectric layer and partially filling the recess, resulting in a first opening including a bottom portion and a top portion on the bottom portion; forming a second inter-dielectric layer on the first inter-dielectric layer, filling the top portion of the first opening, and turning the bottom portion of the first opening into a temporary air gap; partially removing the second inter-dielectric layer to forming a second opening including a top portion penetrating the second inter-dielectric layer, a middle portion derived from the top portion of the first opening, and a bottom portion derived from the temporary air gap; and forming a top electrode layer filling the second opening. The peripheral impurity region, the middle insulating layer, and the top electrode layer together configure a programmable structure.

Due to the design of the semiconductor device of the present disclosure, the programmable structure consisting by the peripheral impurity region, the middle insulating layer, and the top electrode layer may provide an option to change a status of the semiconductor device and an electrical characteristic of the semiconductor device may be changed accordingly. Through tuning the electrical characteristics of the semiconductor device, the quality of the semiconductor device may be improved.

The foregoing has outlined rather broadly the features and technical advantages of the present disclosure in order that the detailed description of the disclosure that follows may be better understood. Additional features and advantages of the disclosure will be described hereinafter and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

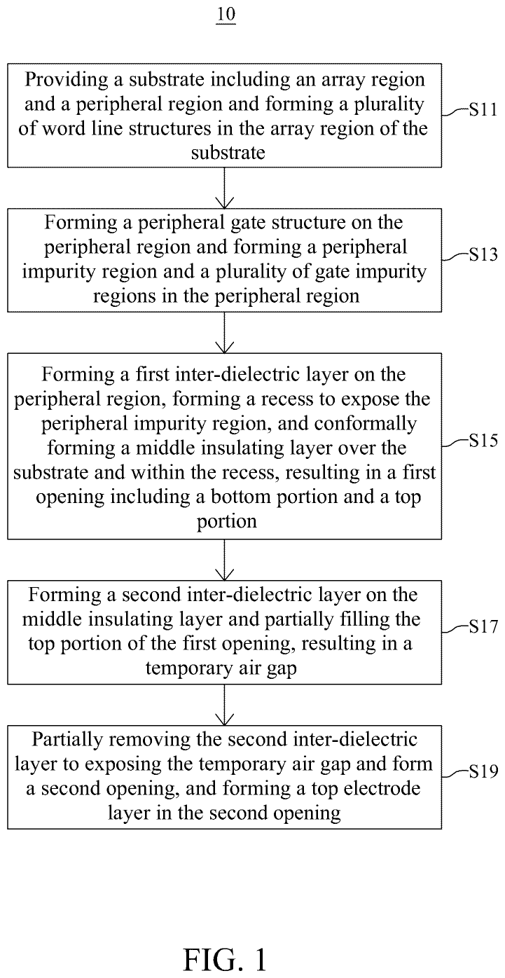

FIG. 1 illustrates, in a flowchart diagram form, a method for fabricating a semiconductor device in accordance with one embodiment of the present disclosure;

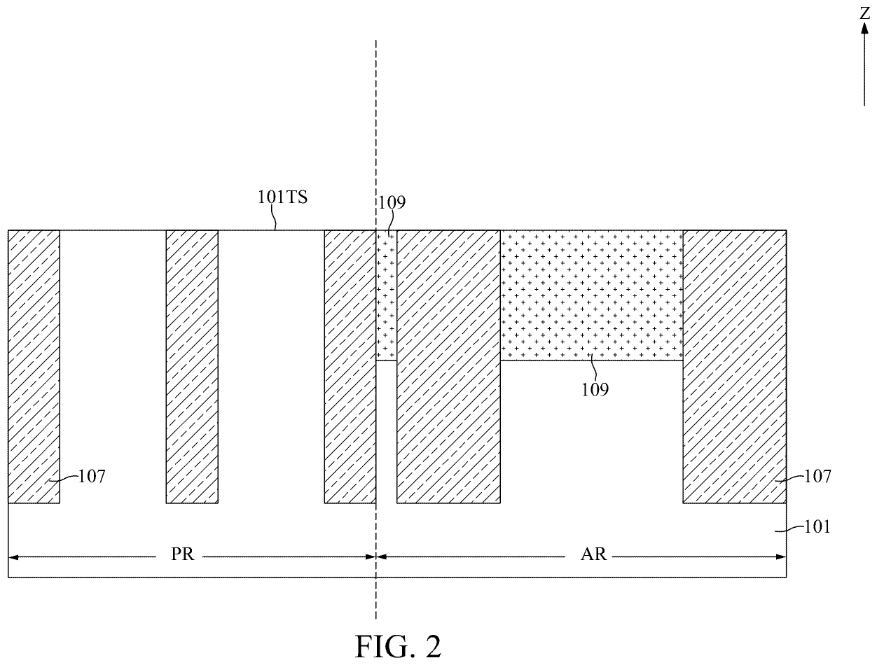

FIGS. 2 to 20 illustrate, in schematic cross-sectional view diagrams, a flow for fabricating the semiconductor device in accordance with one embodiment of the present disclosure;

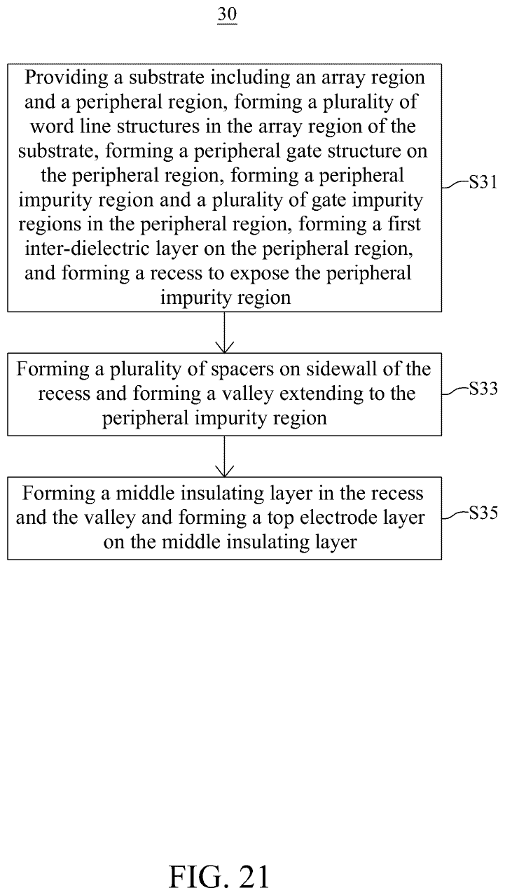

FIG. 21 illustrates, in a flowchart diagram form, a method for fabricating a semiconductor device in accordance with another embodiment of the present disclosure; and

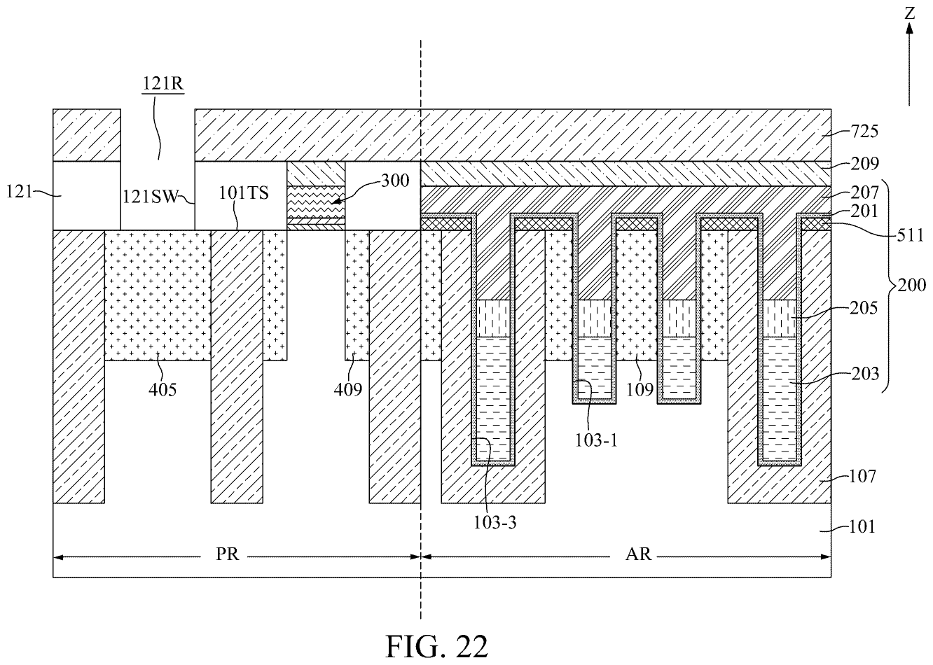

FIGS. 22 to 26 illustrate, in schematic cross-sectional view diagrams, a flow for fabricating the semiconductor device in accordance with another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the direction Z, and below (or down) corresponds to the opposite direction of the arrow of the direction Z.

It should be noted that, in the description of the present disclosure, the terms “forming,” “formed” and “form” may mean and include any method of creating, building, patterning, implanting, or depositing an element, a dopant or a material. Examples of forming methods may include, but are not limited to, atomic layer deposition, chemical vapor deposition, physical vapor deposition, sputtering, co-sputtering, spin coating, diffusing, depositing, growing, implantation, photolithography, dry etching, and wet etching.

It should be noted that, in the description of the present disclosure, the functions or steps noted herein may occur in an order different from the order noted in the figures. For example, two figures shown in succession may in fact be executed substantially concurrently or may sometimes be executed in a reversed order, depending upon the functionalities or steps involved.

FIG. 1 illustrates, in a flowchart diagram form, a method 10 for fabricating a semiconductor device 1A in accordance with one embodiment of the present disclosure. FIGS. 2 to 20 illustrate, in schematic cross-sectional view diagrams, a flow for fabricating the semiconductor device 1A in accordance with one embodiment of the present disclosure.

With reference to FIGS. 1 to 10, at step S11, a substrate 101 including an array region AR and a peripheral region PR may be provided and a plurality of word line structures 200 may be formed in the array region AR of the substrate 101.

With reference to FIG. 2, the substrate 101 may be a bulk semiconductor substrate. The bulk semiconductor substrate may be formed of, for example, an elementary semiconductor such as silicon or germanium or a compound semiconductor such as silicon germanium, silicon carbide, gallium arsenide, gallium phosphide, indium phosphide, indium arsenide, indium antimonide, or other III-V compound semiconductor or II-VI compound semiconductor. In some embodiments, the substrate 101 may have a crystal orientation <100>, <110>, or <111>. In some embodiments, the substrate 101 may have a crystal orientation <100> or <110>. In some embodiments, the bottom portion of the substrate 101 may be amorphous and only the top portion of the substrate 101 is single crystalline. The top portion of the substrate 101 may have a crystal orientation <100>, <110>, or <111>.

With reference to FIG. 2, an isolation layer 107 may be formed in the substrate 101. A series of deposition processes may be performed to deposit a pad oxide layer (not shown) and a pad nitride layer (not shown) on the substrate 101. A photolithography process and a subsequent etching process, such as an anisotropic dry etching process, may be performed to form trenches penetrating through the pad oxide layer, the pad nitride layer, and extending to the substrate 101. An insulating material may be deposited into the trenches and a planarization process, such as chemical mechanical polishing, may be subsequently performed until the top surface 101TS of the substrate 101 is exposed to remove excess filling material, provide a substantially flat surface for subsequent processing steps, and concurrently form the isolation layer 107. The insulating material may be, for example, silicon oxide or other applicable insulating materials.

With reference to FIG. 2, an implantation process may be performed to form a plurality of array impurity regions 109 in the array region AR. The peripheral region PR may be masked during the implantation process. In some embodiments, the array impurity region 109 may include n-type dopants or p-type dopants.

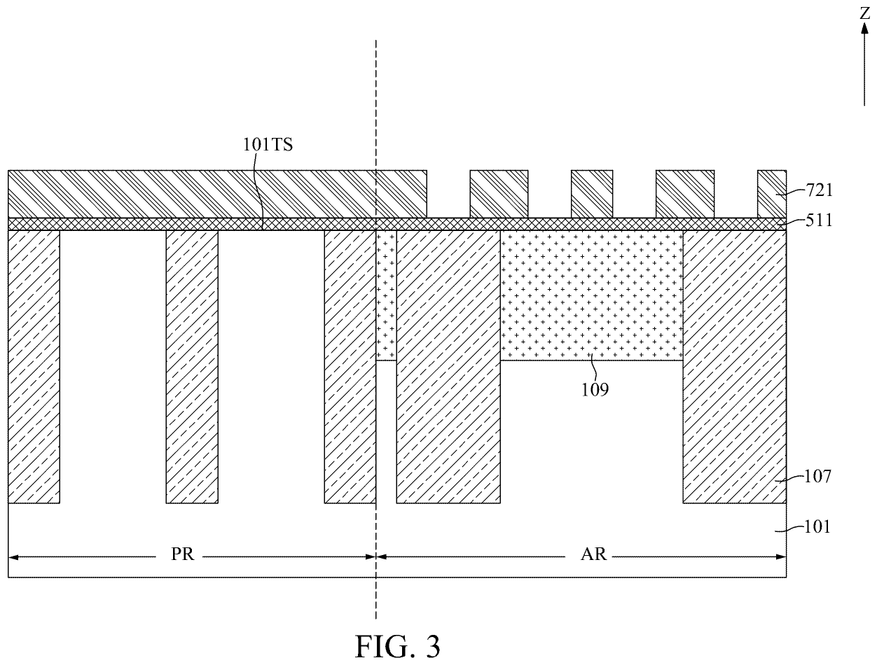

With reference to FIG. 3, a first hard mask layer 511 may be formed on the substrate 101. In some embodiments, the first hard mask layer 511 may be formed of a material having etching selectivity to the substrate 101. In some embodiments, the first hard mask layer 511 may be formed of a material having etching selectivity to the substrate 101 and the isolation layer 107. In some embodiments, the first hard mask layer 511 may be formed of, for example, silicon nitride, boron nitride, silicon boron nitride, phosphorus boron nitride, or boron carbon silicon nitride. In some embodiments, the first hard mask layer 511 may be formed by, for example, atomic layer deposition, chemical vapor deposition, or other applicable deposition processes.

In some embodiments, the first hard mask layer 511 may be formed by a film formation process and a treatment process. Detailedly, in the film formation process, first precursors, which may be boron-based precursors, may be introduced over the substrate 101 to form a boron-based layer. Subsequently, in the treatment process, second precursors, which may be nitrogen-based precursors, may be introduced to react with the boron-based layer and turn the boron-based layer into the first hard mask layer 511.

In some embodiments, the first precursors may be, for example, diborane, borazine, or an alkyl-substituted derivative of borazine. In some embodiments, the first precursors may be introduced at a flow rate between about 5 sccm and about 50 slm (standard liter per minute) or between about 10 sccm and about 1 slm. In some embodiments, the first precursors may be introduced by dilution gas such as nitrogen, hydrogen, argon, or a combination thereof. The dilution gas may be introduced at a flow rate between about 5 sccm and about 50 slm or between about 1 slm and about 10 slm.

In some embodiments, the film formation process may be performed without an assistant of plasma. In such a situation, the substrate temperature of the film formation process may be between about 100° C. and about 1000° C. For example, the substrate temperature of the film formation process may be between about 300° C. and about 500° C. The process pressure of the film formation process may be between about 10 mTorr and about 760 Torr. For example, the process pressure of the film formation process may be between about 2 Torr and about 10 Torr.

In some embodiments, the film formation process may be performed in the presence of plasma. In such a situation, the substrate temperature of the film formation process may be between about 100° C. and about 1000° C. For example, the substrate temperature of the film formation process may be between about 300° C. and about 500° C. The process pressure of the film formation process may be between about 10 mTorr and about 760 Torr. For example, the process pressure of the film formation process may be between about 2 Torr and about 10 Torr. The plasma may be generated by a RF power between 2 W and 5000 W. For example, the RF power may be between 30 W and 1000 W.

In some embodiments, the second precursors may be, for example, ammonia or hydrazine. In some embodiments, the second precursors may be introduced at a flow rate between about 5 sccm and about 50 slm or between about 10 sccm and about 1 slm.

In some embodiments, oxygen-based precursors may be introduced with the second precursors in the treatment process. The oxygen-based precursors may be, for example, oxygen, nitric oxide, nitrous oxide, carbon dioxide, or water.

In some embodiments, silicon-based precursors may be introduced with the second precursors in the treatment process. The silicon-based precursors may be, for example, silane, trisilylamine, trimethylsilane, or silazanes (e.g., hexamethylcyclotrisilazane).

In some embodiments, phosphorus-based precursors may be introduced with the second precursors in the treatment process. The phosphorus-based precursors may be, for example, phosphine.

In some embodiments, oxygen-based precursors, silicon-based precursors, or phosphorus-based precursors may be introduced with the second precursors in the treatment process.

In some embodiments, the treatment process may be performed with an assistant of a plasma process, a UV cure process, a thermal anneal process, or a combination thereof.

When the treatment is performed with the assistance of the plasma process. The plasma of the plasma process may be generated by the RF power. In some embodiments, the RF power may be between about 2 W and about 5000 W at a single low frequency of between about 100 kHz up to about 1 MHz. In some embodiments, the RF power may be between about 30 W and about 1000 W at a single high frequency greater than about 13.6 MHz. In such a situation, a substrate temperature of the treatment process may be between about 20° C. and about 1000° C. The process pressure of the treatment process may be between about 10 mTorr and about 760 Torr.

When the treatment is performed with the assistance of the UV cure process, in such a situation, the substrate temperature of the treatment process may be between about 20° C. and about 1000° C. The process pressure of the treatment process may be between about 10 mTorr and about 760 Torr. The UV cure may be provided by any UV source, such as mercury microwave arc lamps, pulsed xenon flash lamps, or high-efficiency UV light emitting diode arrays. The UV source may have a wavelength of between about 170 nm and about 400 nm. The UV source may provide a photon energy between about 0.5 eV and about 10 eV, or between about 1 eV and about 6 eV. The assistance of the UV cure process may remove hydrogen from the first hard mask layer 511. As hydrogen may diffuse through into other areas of the semiconductor device 1A and may degrade the reliability of the semiconductor device 1A, the removal of hydrogen by the assistance of UV cure process may improve the reliability of the semiconductor device 1A. In addition, the UV cure process may increase the density of the first hard mask layer 511.

When the treatment is performed with the assistant of the thermal anneal process. In such a situation, a substrate temperature of the treatment process may be between about 20° C. and about 1000° C. The process pressure of the treatment process may be between about 10 mTorr and about 760 Torr.

With reference to FIG. 3, a first mask layer 721 may be formed on the first hard mask layer 511. In some embodiments, the first mask layer 721 may be a photoresist layer and may include a pattern of the plurality of word line structures 200.

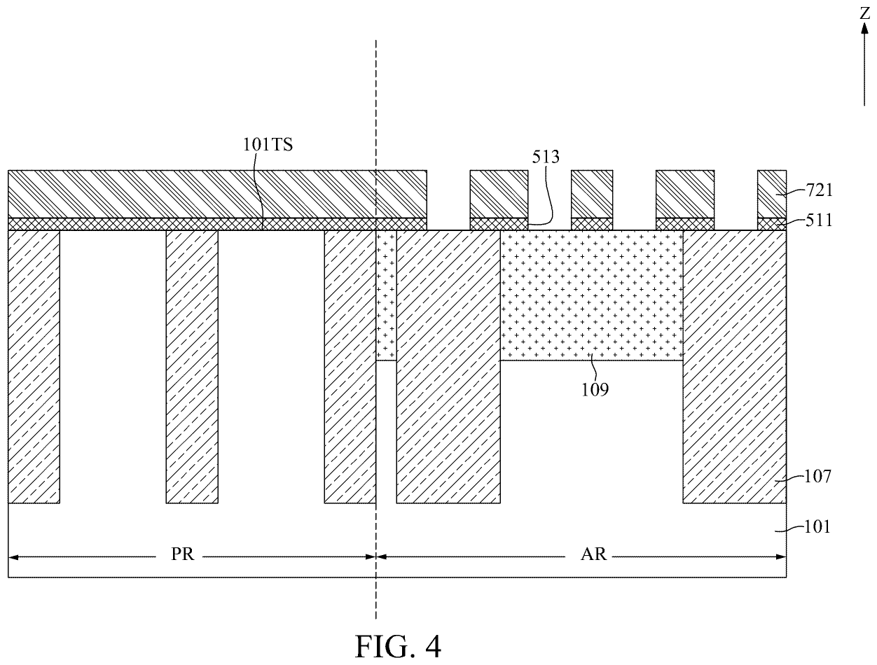

With reference to FIG. 4, an etching process may be performed to remove a portion of the first hard mask layer 511. In some embodiments, the etch rate ratio of the first hard mask layer 511 to the substrate 101 may be between about 100:1 and about 2:1, between about 15:1 and about 2:1, or between about 10:1 and about 2:1 during the etching process. In some embodiments, the etch rate ratio of the first hard mask layer 511 to the isolation layer 107 may be between about 100:1 and about 2:1, between about 15:1 and about 2:1, or between about 10:1 and about 2:1 during the etching process. The pattern of the first mask layer 721 may be transferred to the first hard mask layer 511 and may be referred to as the first pattern 513. Portions of the isolation layer 107 and portions of the substrate 101 may be exposed through the first pattern 513. After the etching process, the first mask layer 721 may be removed by ashing or other applicable processes.

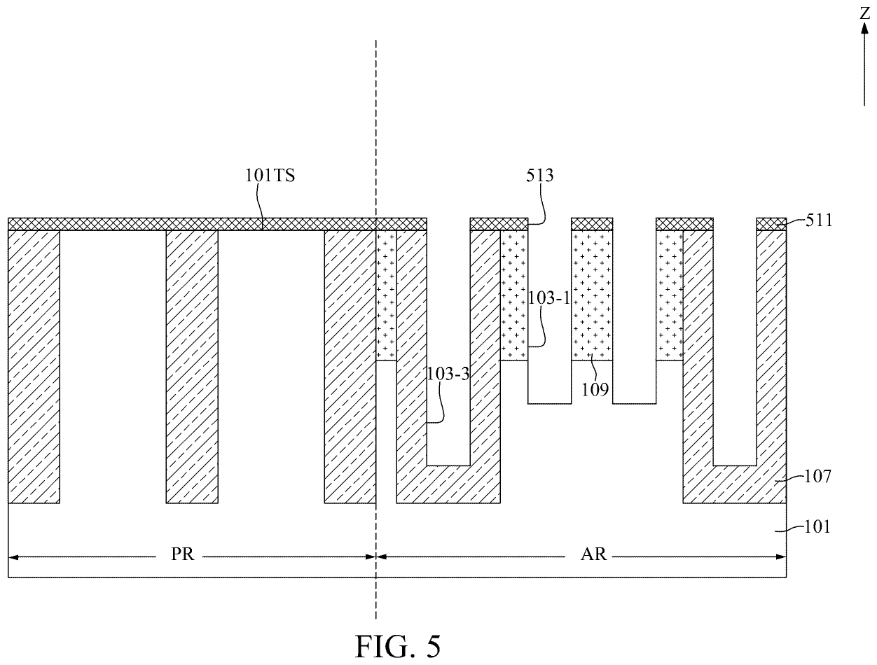

With reference to FIG. 5, a trench etching process may be performed using the first hard mask layer 511 as a mask to remove portions of the isolation layer 107 and portions of the substrate 101 and concurrently form a plurality of word line trenches 103-1, 103-3. In some embodiments, the plurality of word line trenches 103-1 formed in the substrate 101 may be shallower than the plurality of word line trenches 103-3 formed in the isolation layer 107. In some embodiments, the etch rate ratio of the isolation layer 107 to the first hard mask layer 511 may be between about 100:1 and about 5:1, between about 15:1 and about 5:1, or between about 10:1 and about 5:1 during the trench etching process. In some embodiments, the etch rate ratio of the substrate 101 to the first hard mask layer 511 may be between about 80:1 and about 5:1, between about 10:1 and about 5:1, or between about 8:1 and about 5:1 during the trench etching process.

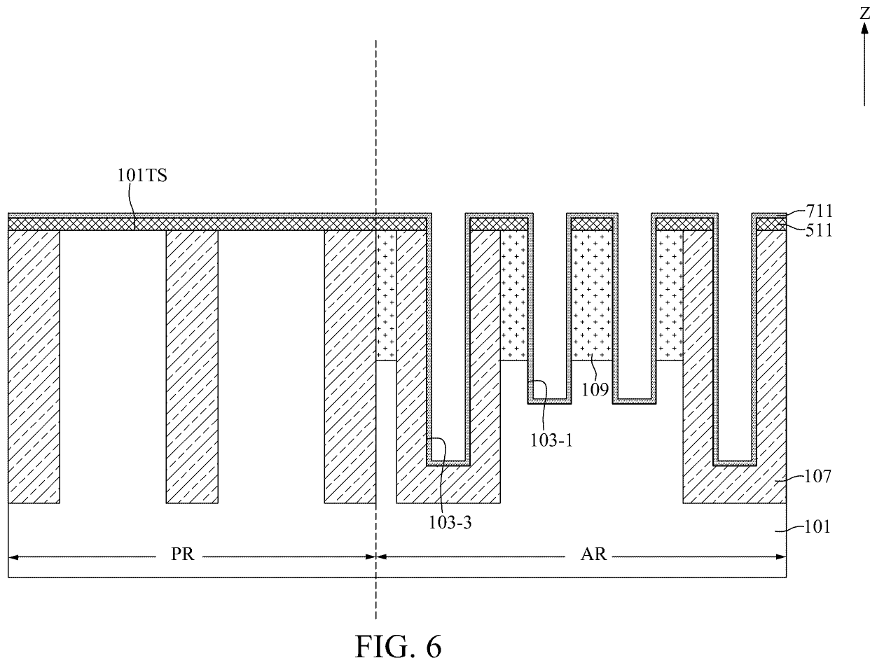

With reference to FIG. 6, a layer of first insulating material 711 may be conformally formed on the first hard mask layer 511 and in the plurality of word line trenches 103-1, 103-3. The layer of first insulating material 711 may have a U-shaped cross-sectional profile in the plurality of word line trenches 103-1, 103-3. In some embodiments, the layer of first insulating material 711 may have a thickness in a range of about 1 nm to about 7 nm, including about 1 nm, about 2 nm, about 3 nm, about 4 nm, about 5 nm, about 6 nm, or about 7 nm.

In some embodiments, the layer of first insulating material 711 may be formed by a thermal oxidation process. For example, the layer of first insulating material 711 may be formed by oxidizing the surface of the plurality of word line trenches 103-1, 103-3. In some embodiments, the layer of first insulating material 711 may be formed by a deposition process such as a chemical vapor deposition or an atomic layer deposition. The first insulating material 711 may include a high-k material, an oxide, a nitride, an oxynitride or combinations thereof. In some embodiments, after a liner polysilicon layer (not shown for clarity) is deposited, the layer of first insulating material 711 may be formed by radical-oxidizing the liner polysilicon layer. In some embodiments, after a liner silicon nitride layer (not shown for clarity) is formed, the layer of first insulating material 711 may be formed by radical-oxidizing the liner silicon nitride layer.

In some embodiments, the high-k dielectric material may include a hafnium-containing material. The hafnium-containing material may be, for example, hafnium oxide, hafnium silicon oxide, hafnium silicon oxynitride, or a combination thereof. In some embodiments, the high-k dielectric material may be, for example, lanthanum oxide, lanthanum aluminum oxide, zirconium oxide, zirconium silicon oxide, zirconium silicon oxynitride, aluminum oxide or a combination thereof.

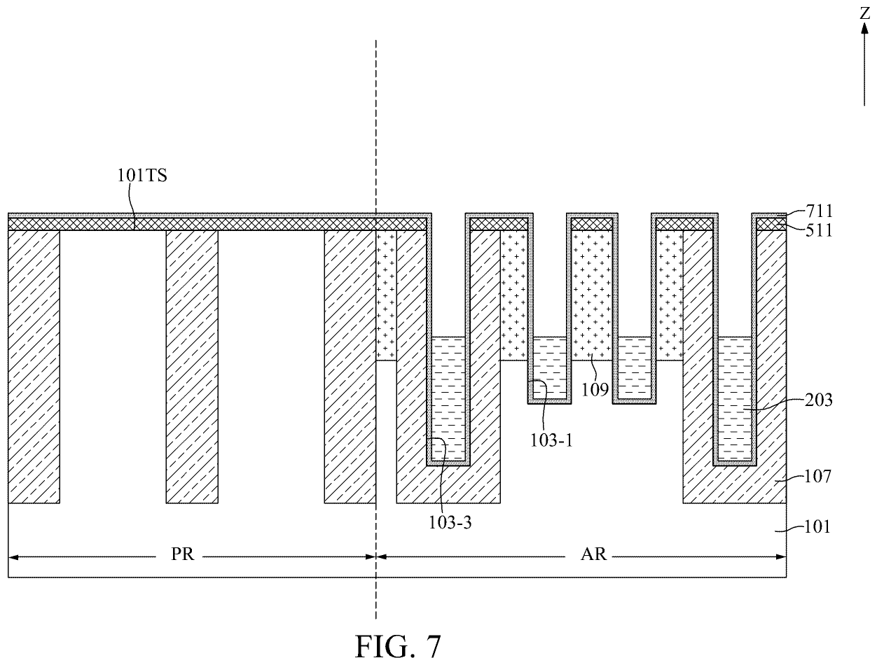

With reference to FIG. 7, a plurality of word line bottom conductive layers 203 may be formed in the plurality of word line trenches 103-1, 103-3, respectively and correspondingly. For example, a conductive material (not shown) may be formed to fill the plurality of word line trenches 103-1, 103-3. An etching back process may be subsequently performed to partially remove the conductive material formed in the plurality of word line trenches 103-1, 103-3 and concurrently form the plurality of word line bottom conductive layers 203. In some embodiments, the conductive material may be a work function material such as, titanium, titanium nitride, silicon, silicon germanium, or a combination thereof. It should be noted that the term “work function” refers to the bulk chemical potential of a material (e.g., metal) relative to the vacuum level.

For example, in the present embodiment, the conductive material is titanium nitride and may be formed by chemical vapor deposition. In some embodiments, the deposition of the conductive material may include a source gas introducing step, a first purging step, a reactant flowing step, and a second purging step. The source gas introducing step, the first purging step, the reactant flowing step, and the second purging step may be referred to as one cycle. Multiple cycles may be performed to fill the plurality of word line trenches 103-1, 103-3.

Detailedly, the intermediate semiconductor device illustrated in FIG. 6 may be loaded in a reaction chamber. In the source gas introducing step, source gases containing a precursor and a reactant may be introduced to the reaction chamber containing the intermediate semiconductor device. The precursor and the reactant may diffuse across the boundary layer and reach the surface of the intermediate semiconductor device. The precursor and the reactant may adsorb on and subsequently migrate on the surface aforementioned. The adsorbed precursor and the adsorbed reactant may react on the surface aforementioned and form solid byproducts. The solid byproducts may form nuclei on the surface aforementioned. The nuclei may grow into islands and the islands may merge into a continuous thin film on the surface aforementioned. In the first purging step, a purge gas such as argon may be injected into the reaction chamber to purge out the gaseous byproducts, unreacted precursor, and unreacted reactant.

In the reactant flowing step, the reactant may be solely introduced to the reaction chamber to turn the continuous thin film into a titanium nitride layer. In the second purging step, a purge gas such as argon may be injected into the reaction chamber to purge out the gaseous byproducts and unreacted reactant.

In some embodiments, the deposition of the conductive material using chemical vapor deposition may be performed with the assistance of plasma. The source of the plasma may be, for example, argon, hydrogen, or a combination thereof.

For example, the precursor may be titanium tetrachloride. The reactant may be ammonia. Titanium tetrachloride and ammonia may react on the surface and form a titanium nitride layer including high chloride contamination due to incomplete reaction between titanium tetrachloride and ammonia. The ammonia in the reactant flowing step may reduce the chloride content of the titanium nitride layer.

In some embodiments, the etch rate ratio of the word line bottom conductive layer 203 to the first insulating material 711 may be between about 100:1 and about 5:1, between about 15:1 and about 5:1, or between about 10:1 and about 5:1 during the etching back process.

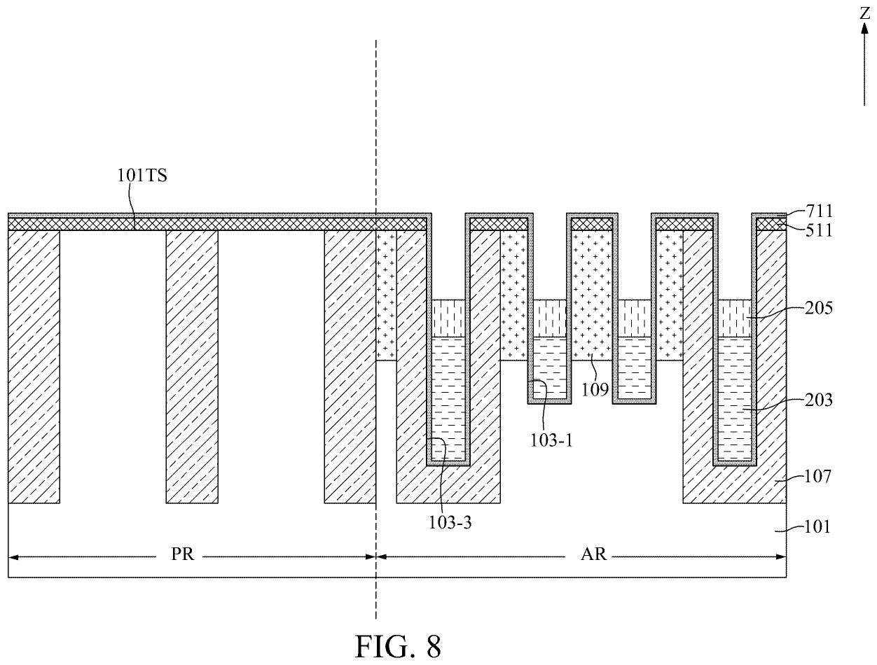

With reference to FIG. 8, a plurality of word line top conductive layers 205 may be formed in the plurality of word line trenches 103-1, 103-3. In some embodiments, the plurality of word line top conductive layers 205 may be formed of, for example, polycrystalline silicon, polycrystalline germanium, polycrystalline silicon germanium, doped polycrystalline doped polycrystalline germanium, doped polycrystalline silicon germanium, or a combination thereof. In some embodiments, the plurality of word line top conductive layers 205 may be doped with p-type dopants or n-type dopants. In some embodiments, a conductive material such as polycrystalline silicon, polycrystalline germanium, or polycrystalline silicon germanium may be deposited into the plurality of word line trenches 103-1, 103-3. An etching back process may be subsequently performed to remove portions of the conductive to form the plurality of word line top conductive layers 205. In some embodiments, the dopants may be incorporated into the deposition process of the conductive material. In some embodiments, the dopants may be doped using an implantation process after the etching back process.

The term “p-type dopant” refers to an impurity that when added to an intrinsic semiconductor material creates deficiencies of valence electrons. In a silicon containing semiconductor material, examples of p-type dopants include, but are not limited to, boron, aluminum, gallium or indium. The term “n-type dopant” refers to an impurity that when added to an intrinsic semiconductor material contributes free electrons to the intrinsic semiconductor material. In a silicon-containing material, examples of n-type dopants include, but are not limited to, antimony, arsenic or phosphorus.

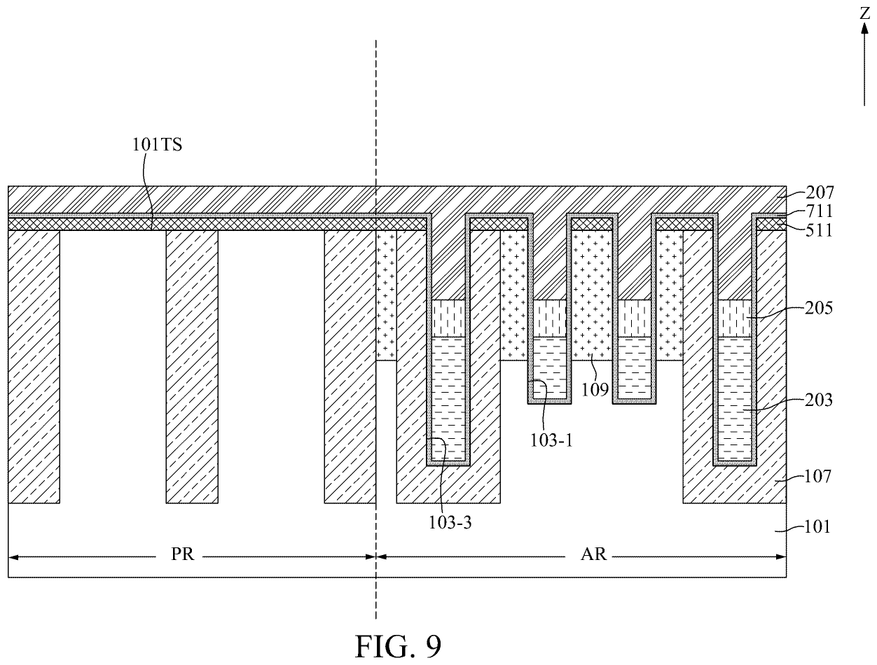

With reference to FIG. 9, a word line capping layer 207 may be formed on the first hard mask layer 511 to completely fill the plurality of word line trenches 103-1, 103-3. In some embodiments, the word line capping layer 207 may be formed of, for example, silicon nitride, silicon oxynitride, silicon nitride oxide, or other applicable dielectric material. In some embodiments, the word line capping layer 207 may be formed by, for example, chemical vapor deposition, plasma-enhanced chemical vapor deposition, or other applicable deposition processes. A planarization process, such as chemical mechanical polishing, may be performed to remove excess material and provide a substantially flat surface for subsequent processing steps.

It should be noted that, in the present disclosure, silicon oxynitride refers to a substance which contains silicon, nitrogen, and oxygen and in which a proportion of oxygen is greater than that of nitrogen. Silicon nitride oxide refers to a substance which contains silicon, oxygen, and nitrogen and in which a proportion of nitrogen is greater than that of oxygen.

With reference to FIG. 1 and FIGS. 11 to 13, at step S13, a peripheral gate structure 300 may be formed on the peripheral region PR and a peripheral impurity region 405 and a plurality of gate impurity regions 409 may be formed in the peripheral region PR.

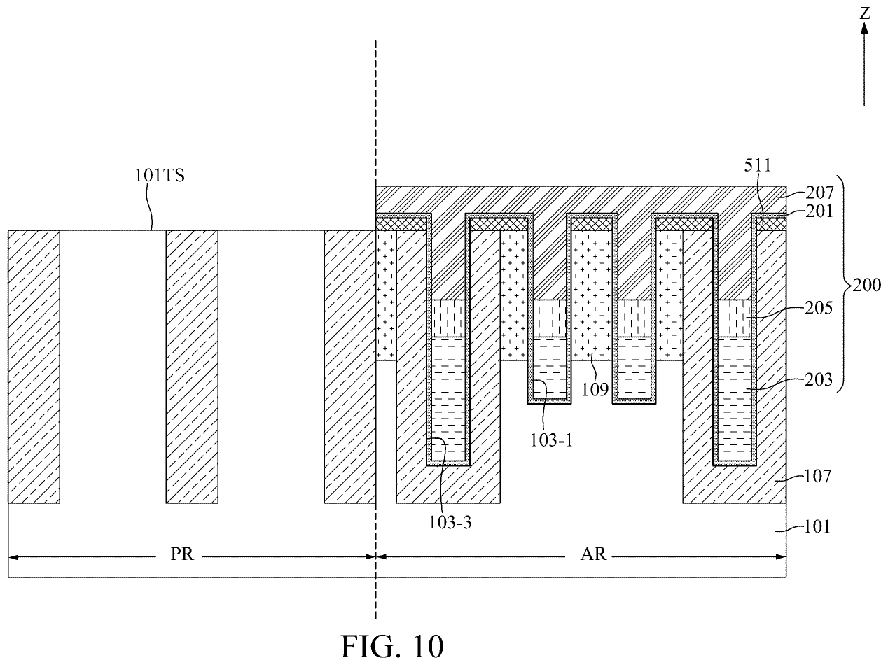

With reference to FIG. 10, a mask layer (not shown for clarity) may be formed over the array region AR of the substrate 101 to cover the word line capping layer 207 formed over the array region AR of the substrate 101. An etching process may be performed to remove the word line capping layer 207, the layer of first insulating material 711, and the first hard mask layer 511 formed over the peripheral region PR of the substrate 101. The remaining first insulating material 711 may be referred to as the word line dielectric layer 201. The word line dielectric layer 201, the plurality of word line bottom conductive layers 203, the plurality of word line top conductive layers 205, and the word line capping layer 207 together configure the plurality of word line structures 200.

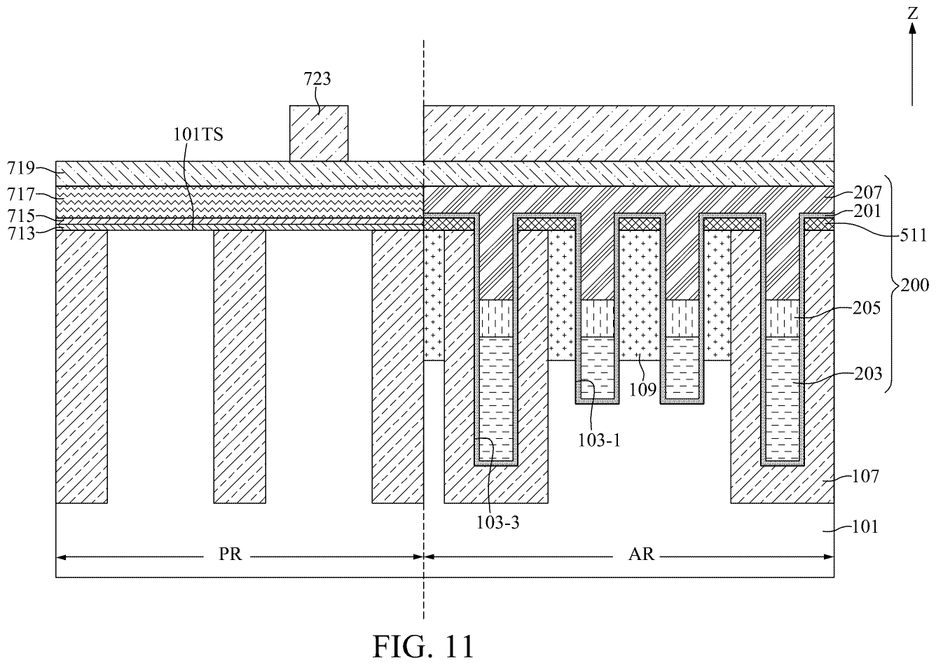

With reference to FIG. 11, a layer of gate insulating material 713 may be conformally formed on the top surface 101TS of the peripheral region PR of the substrate 101. In some embodiments, the layer of gate insulating material 713 may include, for example, oxides, nitrides, oxynitrides, silicates (e.g., metal silicates), aluminates, titanates, nitrides, high-k dielectric materials, or a combination thereof. In some embodiments, the layer of gate insulating material 713 may be formed by suitable deposition processes, for example, atomic layer deposition, chemical vapor deposition, plasma-enhanced chemical vapor deposition, evaporation, chemical solution deposition, or other suitable deposition processes. In some embodiments, the layer of gate insulating material 713 may be formed by oxidizing the top surface 101TS of the substrate 101. In some embodiments, the thickness of the layer of gate insulating material 713 may vary depending on the deposition process as well as the composition and number of materials used. For example, the thickness of the layer of gate insulating material 713 may be between about 10 angstroms and about 50 angstroms. In some embodiments, the layer of gate insulating material 713 may include a multi-layered structure. For example, the layer of gate insulating material 713 may be an oxide-nitride-oxide (ONO) structure. For another example, the layer of gate insulating material 713 may include a bottom layer formed of silicon oxide and a top layer formed of high-k dielectric materials.

Examples of high-k dielectric materials (with a dielectric constant greater than 7.0) include, but are not limited to, metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k dielectric materials may further include dopants such as, for example, lanthanum and aluminum.

In some embodiments, an interfacial layer (not shown) may be optionally formed between the substrate 101 and the layer of gate insulating material 713. The interfacial layer may be formed of, for example, silicon oxide, silicon nitride, silicon oxynitride, other semiconductor oxides, or a combination thereof. The interfacial layer may be formed to any suitable thickness using any suitable process including thermal growth, atomic layer deposition, chemical vapor deposition, high-density plasma chemical vapor deposition, spin-on deposition, or other suitable deposition processes. For example, the thickness of the interfacial layer may be between about 7 angstroms and 12 angstroms or between about 8 angstroms and 10 angstroms. The interfacial layer may facilitate the formation of the layer of gate insulating material 713.

With reference to FIG. 11, a layer of gate bottom conductive material 715 may be formed on the layer of gate insulating material 713. In some embodiments, the layer of gate bottom conductive material 715 may be formed of, for example, polycrystalline silicon, polycrystalline germanium, polycrystalline silicon germanium, doped polycrystalline silicon, doped polycrystalline germanium, doped polycrystalline silicon germanium, or other suitable conductive material. In some embodiments, the layer of gate bottom conductive material 715 may be doped with p-type dopants or n-type dopants.

With reference to FIG. 11, a layer of gate top conductive material 717 may be formed on the layer of gate bottom conductive material 715. In some embodiments, the gate top conductive material 717 may be, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof.

With reference to FIG. 11, a layer of top capping material 719 may be formed over the substrate 101 to cover the word line capping layer 207 and the layer of gate top conductive material 717. In some embodiments, the top capping material 719 may be, for example, silicon nitride, silicon oxide, or other applicable dielectric materials. In some embodiments, the layer of top capping material 719 may be formed by, for example, chemical vapor deposition or other applicable deposition processes. A second mask layer 723 may be formed on the layer of top capping material 719. In some embodiments, the second mask layer 723 may be a photoresist layer and have a pattern of the peripheral gate structure 300. The second mask layer 723 may cover the array region AR.

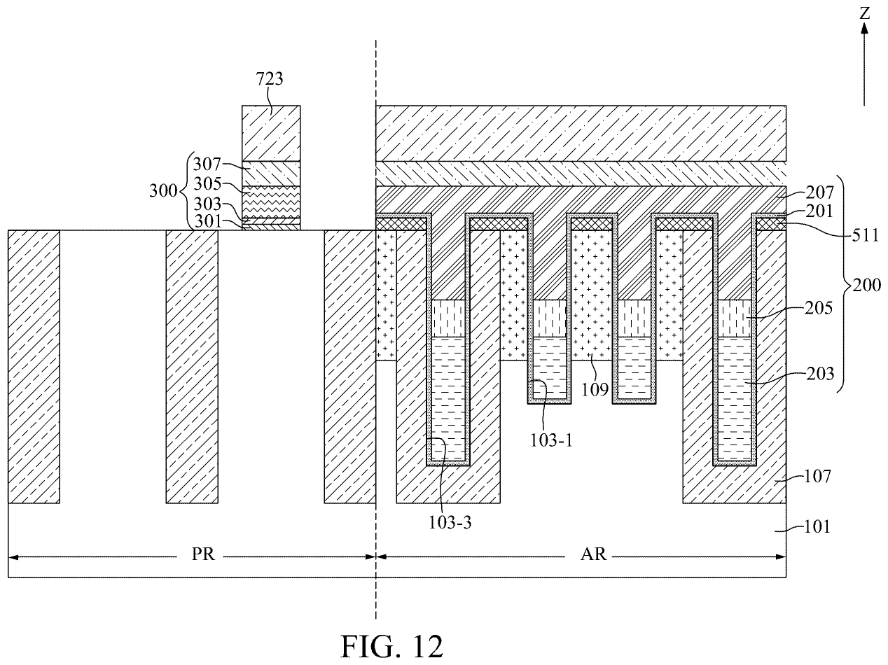

With reference to FIG. 12, an etching process may be performed using the second mask layer 723 as a mask to remove the portions, which are not masked by the second mask layer 723, of the top capping material 719, the gate top conductive material 717, the gate bottom conductive material 715, and the gate insulating material 713. In some embodiments, the etching process may be a multi-stage dry etching process. The etching chemistry may be different for each stage to provide different etching selectivity.

The remaining top capping material 719 over the peripheral region PR, the remaining gate top conductive material 717, the remaining gate bottom conductive material 715, and the remaining gate insulating material 713 may be referred to as a top capping layer 307, a gate top conductive layer 305, a gate bottom conductive layer 303, and a gate dielectric layer 301, respectively and correspondingly. The gate dielectric layer 301, the gate bottom conductive layer 303, the gate top conductive layer 305, and the top capping layer 307 together configure the peripheral gate structure 300. The second mask layer 723 may be removed after the formation of the peripheral gate structure 300. The remaining top capping material 719 on the word line capping layer 207 may be referred to as the top capping layer 209.

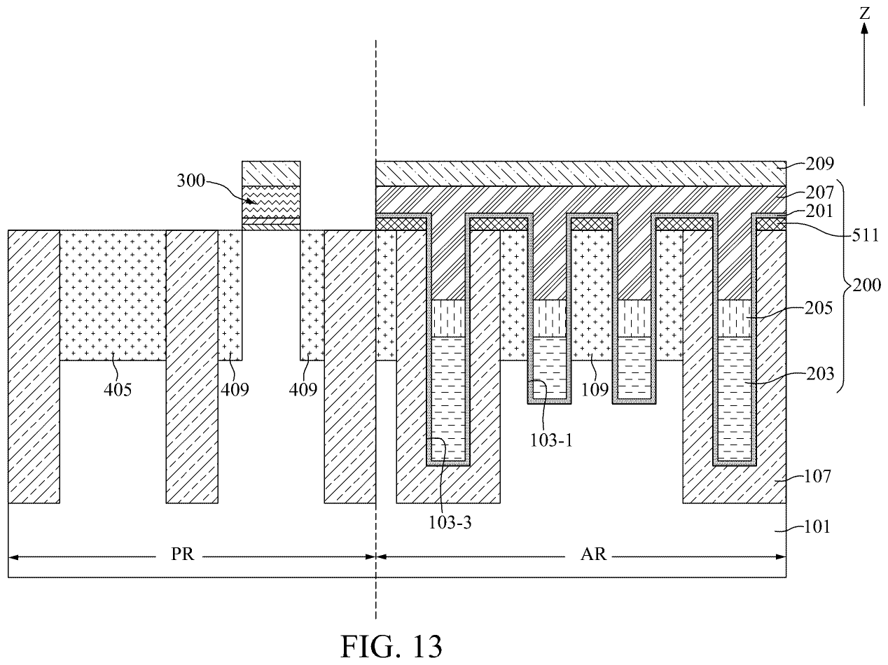

With reference to FIG. 13, an implantation process may be performed using the peripheral gate structure 300 as the mask to form the peripheral impurity region 405 and the plurality of gate impurity regions 409. The plurality of gate impurity regions 409 may be formed in the peripheral region PR and adjacent to the peripheral gate structure 300. The peripheral impurity region 405 may be formed in the peripheral region PR distant from the peripheral gate structure 300 and may be laterally surrounded by the isolation layer 107. The peripheral impurity region 405 and the plurality of gate impurity regions 409 may include n-type dopants or p-type dopants.

With reference to FIG. 1 and FIGS. 14 to 16, at step S15, a first inter-dielectric layer 121 may be formed on the peripheral region PR, a recess 121R may be formed to expose the peripheral impurity region 405, and a middle insulating layer 401 may be conformally form over the substrate 101 and within the recess 121R, resulting in a first opening 130 including a bottom portion 131 and a top portion 133.

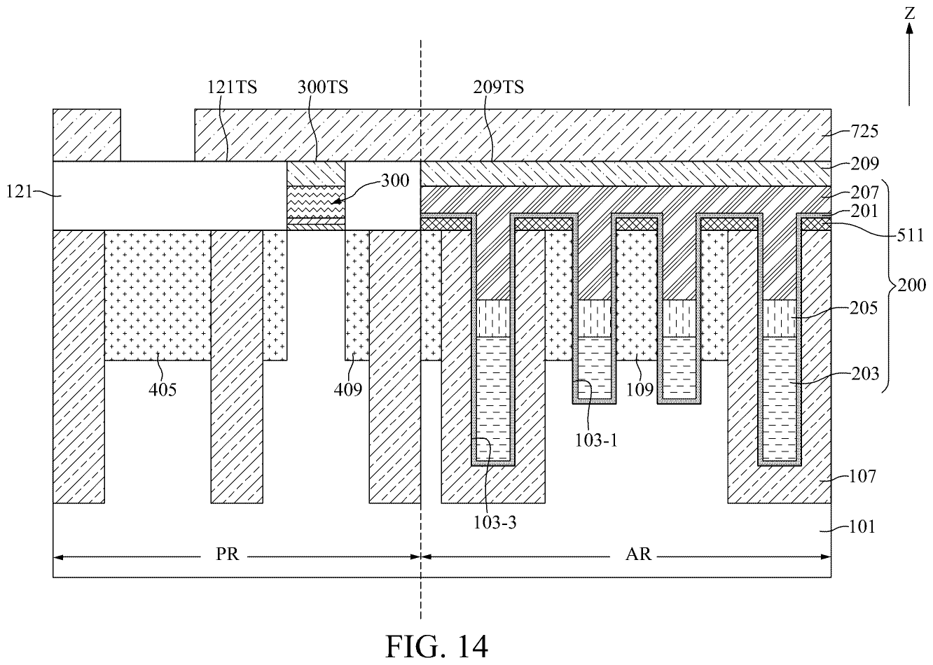

With reference to FIG. 14, the first inter-dielectric layer 121 may be formed over the substrate 101 and covering the peripheral gate structure 300 and the top capping layer 209. A planarization process, such as chemical mechanical polishing, may be performed until the top surface 209TS of the top capping layer 209 to remove excess material and provide a substantially flat surface for subsequent processing steps. The top surface 121TS of the first inter-dielectric layer 121, the top surface 300TS of the peripheral gate structure 300, and the top surface 209TS of the top capping layer 209 may be substantially coplanar.

In some embodiments, the first inter-dielectric layer 121 may be formed of, for example, silicon oxide or other applicable dielectric materials. In some embodiments, the first inter-dielectric layer 121 may be formed by, for example, chemical vapor deposition or other applicable deposition processes.

With reference to FIG. 14, a third mask layer 725 may be formed on the first inter-dielectric layer 121 and the top capping layer 209. In some embodiments, the third mask layer 725 may be a photoresist layer. The third mask layer 725 may include a pattern of the recess 121R which partially exposes the top surface 121TS of the first inter-dielectric layer 121.

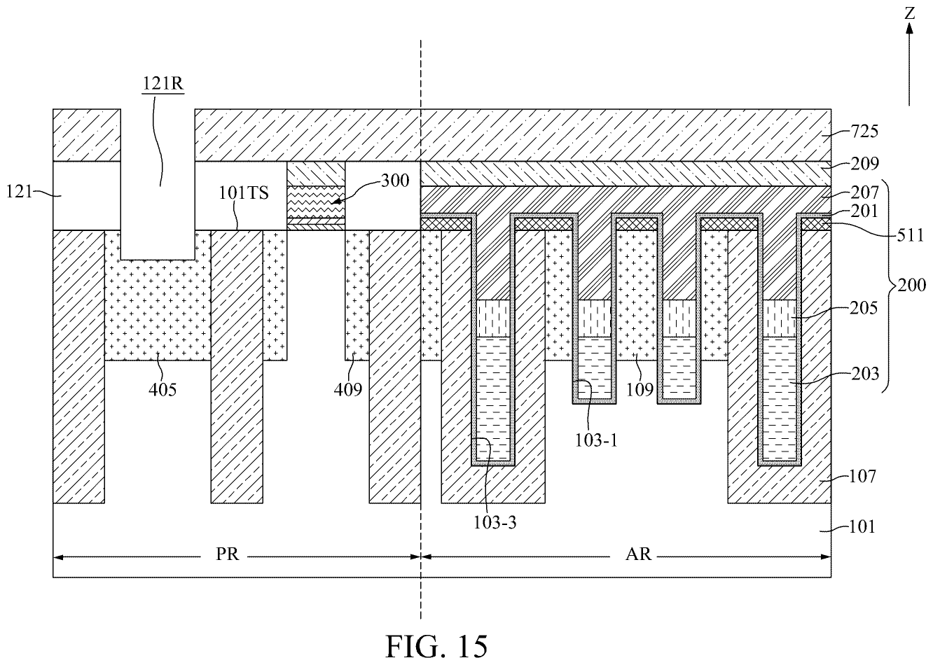

With reference to FIG. 15, an etching process may be performed using the third mask layer 725 as the mask to remove a portion of the first inter-dielectric layer 121 and the peripheral impurity region 405. After the etching process, a recess 121R may be formed.

The bottom of the recess 121R may be lower than the top surface 101TS of the substrate 101. The third mask layer 725 may be removed after the formation of the recess 121R.

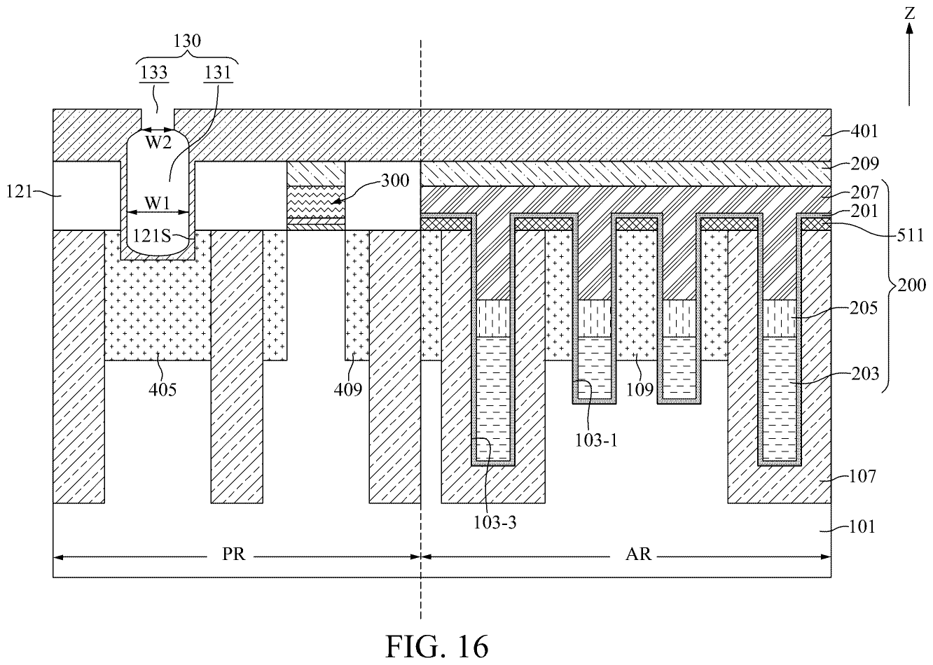

With reference to FIG. 16, the middle insulating layer 401 may be conformally formed on the first inter-dielectric layer 121, on the top capping layer 209, and partially in the recess 121R. The middle insulating layer 401 may extend into the recess 121R to line the surface 121S (i.e., sidewalls and bottom surface) of the recess 121R, resulting in a first opening 130 including the bottom portion 131 and the top portion 133. The top portion 133 may be located above the top surface 121TS of the first inter-dielectric layer 121. The width W1 of the bottom portion 131 may be greater than the width W2 of the top portion 133. In some embodiments, the middle insulating layer 401 may have a neck portion located at the top portion 133 of the first opening 130.

In some embodiments, the middle insulating layer 401 may be formed of, for example, oxides, nitrides, oxynitrides, silicates (e.g., metal silicates), aluminates, titanates, nitrides, high-k dielectric materials, or a combination thereof. In some embodiments, the middle insulating layer 401 may be formed by suitable deposition processes, for example, chemical vapor deposition, plasma-enhanced chemical vapor deposition, or other suitable deposition processes.

Examples of high-k dielectric materials (with a dielectric constant greater than 7.0) include, but are not limited to, metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k dielectric materials may further include dopants such as, for example, lanthanum and aluminum.

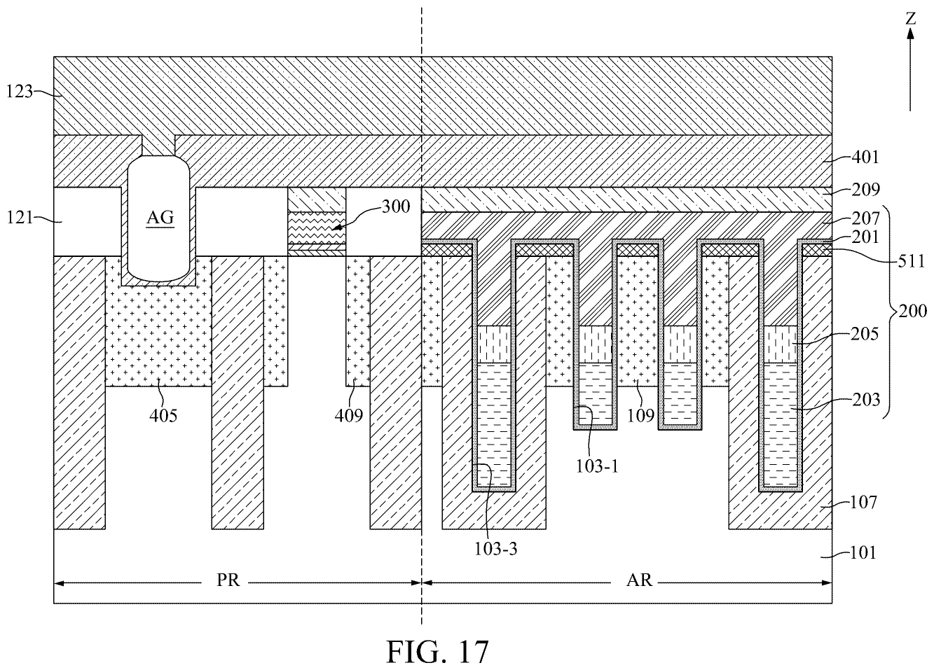

With reference to FIGS. 1 and 17, at step S17, a second inter-dielectric layer 123 may be formed on the middle insulating layer 401 and partially filling the top portion 133 of the first opening 130, resulting in a temporary air gap AG.

With reference to FIG. 17, the second inter-dielectric layer 123 may be formed of, for example, silicon oxide or other applicable dielectric materials. In some embodiments, the second inter-dielectric layer 123 may be formed by, for example, chemical vapor deposition or other applicable deposition processes. A planarization process, such as chemical mechanical polishing, may be performed to remove excess material and provide a substantially flat surface for subsequent processing steps.

With reference to FIG. 1 and FIGS. 18 to 20, at step S19, the second inter-dielectric layer 123 may be partially removed to exposing the temporary air gap AG and form a second opening 140, and a top electrode layer 403 may be formed in the second opening 140.

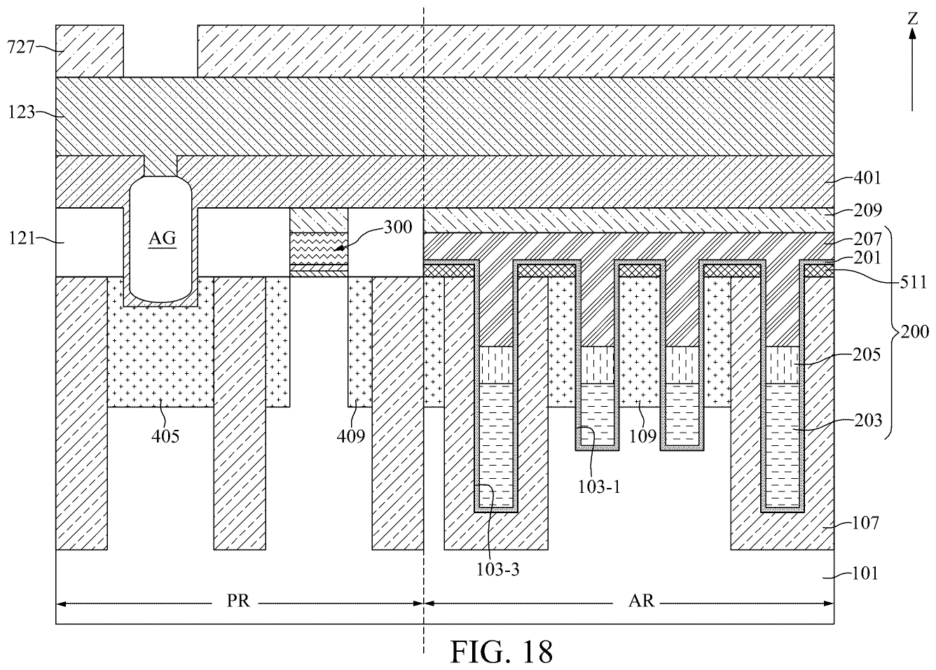

With reference to FIG. 18, a fourth mask layer 727 may be formed on the second inter-dielectric layer 123. In some embodiments, the fourth mask layer 727 may be a photoresist layer and may include the pattern of the second opening 140.

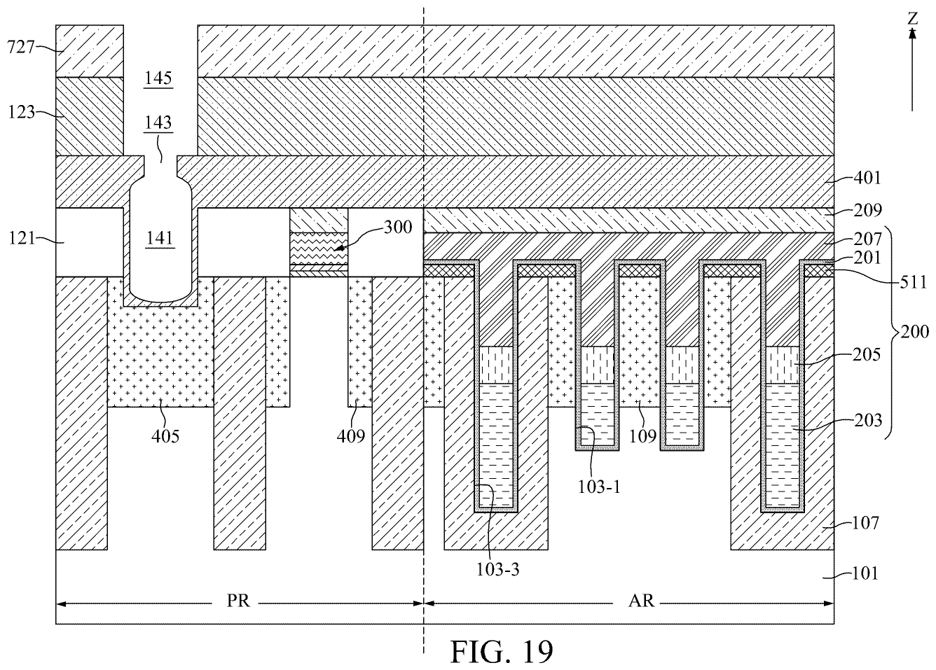

With reference to FIG. 19, an etching process may be performed using the fourth mask layer 727 as the mask to remove portions of the second inter-dielectric layer 123 and the middle insulating layer 401 to expose the temporary air gap AG and form the second opening 140. The second opening 140 may include a bottom portion 141, a middle portion 143, and a top portion 145. The bottom portion 141 of the second opening 140 may be derived from the temporary air gap AG. The middle portion 143 of the second opening 140 may be derived from the top portion 133 of the first opening 130. The top portion 145 of the second opening 140 may penetrate the second inter-dielectric layer 123 and communicate with the middle portion 143 and bottom portion 141 of the second opening 140. The fourth mask layer 727 may be removed after the formation of the second opening 140.

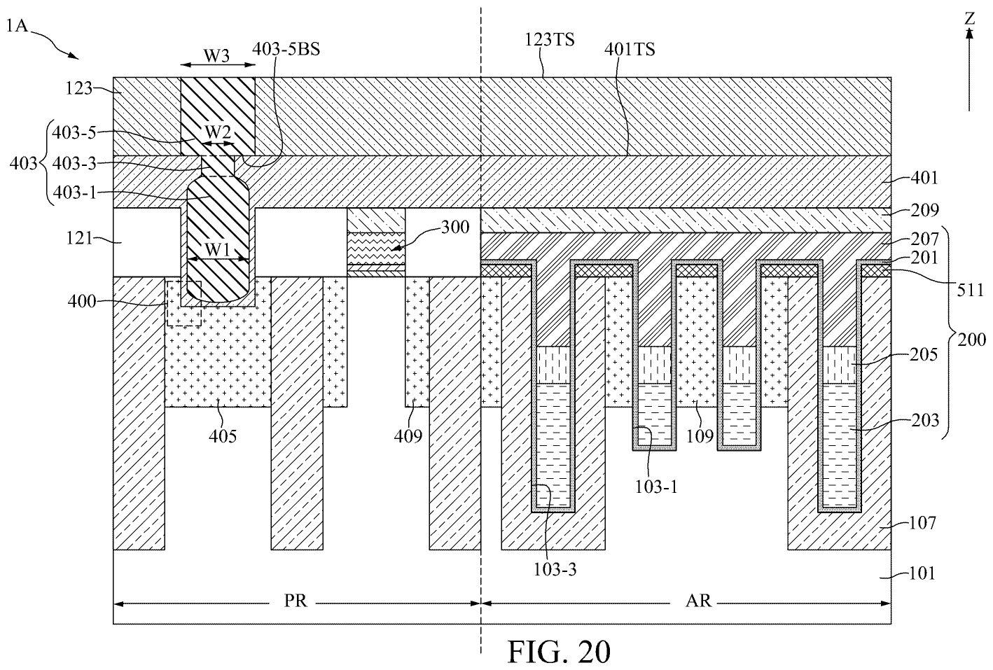

With reference to FIG. 20, a conductive material (not shown) may be formed to fill the second opening 140. A planarization process, such as chemical mechanical polishing, may be performed until the top surface 123TS of the second inter-dielectric layer 123 is exposed to remove excess material, provide a substantially flat surface for subsequent processing steps, and concurrently form the top electrode layer 403. In some embodiments, the conductive material may include, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. In some embodiments, the conductive material may be formed by, for example, physical vapor deposition, chemical vapor deposition, sputtering, electroplating, electroless plating, or other suitable deposition processes.

In some embodiments, the top electrode layer 403 may include a bottom portion 403-1, a middle portion 403-3, and a top portion 403-5. The bottom portion 403-1 may be formed at the bottom portion 141 of the second opening 140 and may be surrounded by the middle insulating layer 401. The middle portion 403-3 may be formed at the middle portion 143 of the second opening 140, on the bottom portion 403-1, and laterally surrounded by the middle insulating layer 401. The top portion 403-5 may be formed at the top portion 145 of the second opening 140, on the middle portion 403-3, and laterally surrounded by the second inter-dielectric layer 123 and the middle insulating layer 401. In some embodiments, the bottom surface 403-5BS of the top portion 403-5 may be lower than the top surface 401TS of the middle insulating layer 401. In some embodiments, the bottom portion 403-1 of the top electrode layer 403 may have a bottle-shaped profile in a cross-sectional perspective.

With reference to FIG. 20, the peripheral impurity region 405, the middle insulating layer 401, and the top electrode layer 403 together configure a programmable structure 400 such as an anti-fuse. An anti-fuse is non-conductive in the native unprogrammed state and becomes conductive when programmed. For example, the anti-fuse may be constructed with a thin dielectric layer sandwiched between two conductors. In some embodiments, the peripheral impurity region 405 may serve as the lower conductor of the programmable structure 400. The top electrode layer 403 may serve as the upper conductor of the programmable structure 400. The middle insulating layer 401 may serve as the dielectric layer sandwiched between the lower and the upper conductors.

When programming the programmable structure 400, a programming voltage may be applied to the top electrode layer 403 and the peripheral impurity region 405 may be grounded, the middle insulating layer 401 sandwiched by the top electrode layer 403 and the peripheral impurity region 405 may be stressed under the programming voltage. As a result, the middle insulating layer 401 will rupture to form a contiguous path connecting the top electrode layer 403 and the peripheral impurity region 405. In other words, the middle insulating layer 401 may be blown out and the programmable structure 400 is programmed.

With reference to FIG. 20, in some embodiments, the width W1 of the bottom portion 403-1 may be greater than the width W2 of the middle portion 403-3. In some embodiments, the width W3 of the top portion 403-5 may be greater than the width W2 of the middle portion 403-3. In some embodiments, the width W3 of the top portion 403-5 may be greater than the width W1 of the bottom portion 403-1. The narrower middle portion 403-3 of the top electrode layer 403 may also configure another programmable structure such as an e-fuse, along with the bottom portion 403-1 and top portion 403-5 of the top electrode layer 403. By integrating the programmable structures, the integration of the semiconductor device 1A may be increased.

FIG. 21 illustrates, in a flowchart diagram form, a method 30 for fabricating a semiconductor device 1B in accordance with another embodiment of the present disclosure. FIGS. 22 to 26 illustrate, in schematic cross-sectional view diagrams, a flow for fabricating the semiconductor device 1B in accordance with another embodiment of the present disclosure.

With reference to FIGS. 21 and 22, at step S31, a substrate 101 including an array region AR and a peripheral region PR may be provided, a plurality of word line structures 200 may be formed in the array region AR of the substrate 101, a peripheral gate structure 300 may be formed on the peripheral region PR, a peripheral impurity region 405 and a plurality of gate impurity regions 409 may be formed in the peripheral region PR, a first inter-dielectric layer 121 may be formed on the peripheral region PR, and a recess 121R may be formed to expose the peripheral impurity region 405.

With reference to FIG. 22, an intermediate semiconductor device may be fabricated with a procedure similar to that illustrated in FIGS. 2 to 14, and descriptions thereof are not repeated herein. An etching process may be performed using the third mask layer 725 as the mask to remove a portion of the first inter-dielectric layer 121. After the etching process, a recess 121R may be formed. The bottom of the recess 121R may be substantially coplanar with the top surface 101TS of the substrate 101. The third mask layer 725 may be removed after the formation of the recess 121R.

With reference to FIGS. 21, 23, and 24, at step S33, a plurality of spacers 407 may be formed on sidewall 121SW of the recess 121R and a valley 105 may be formed extending to the peripheral impurity region 405.

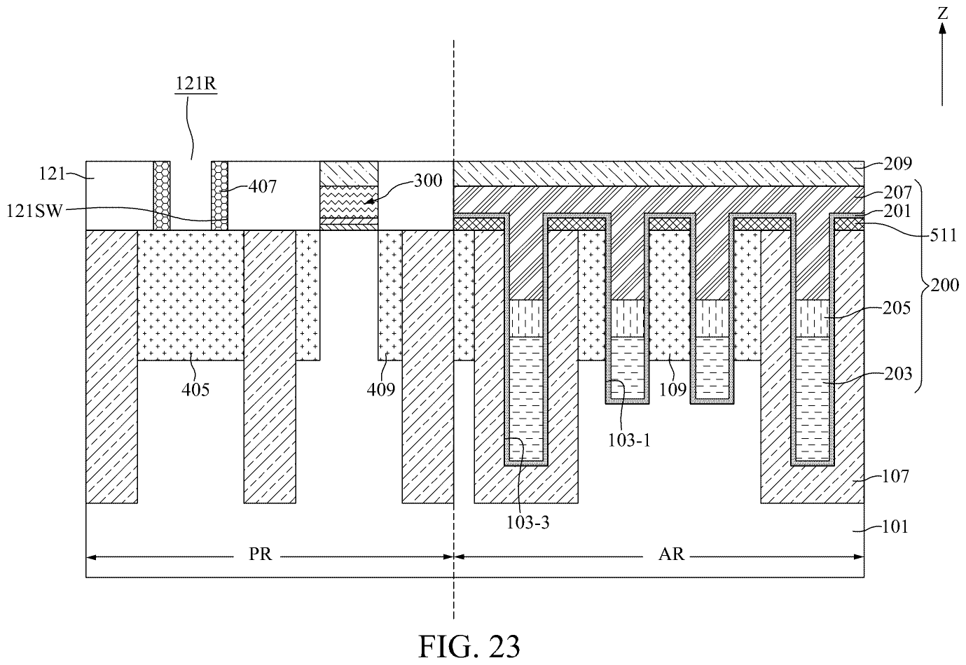

With reference to FIG. 23, a plurality of spacers 407 may be formed on sidewalls 121SW of the recess 121R. In some embodiments, the plurality of spacers 407 may be formed of, for example, semiconductor oxides, semiconductor nitrides, semiconductor oxynitrides, semiconductor carbides, or other suitable dielectric materials. In some embodiments, the plurality of spacers 407 may be formed by conformally depositing a layer of spacer material (not shown) with a subsequent anisotropic etching process.

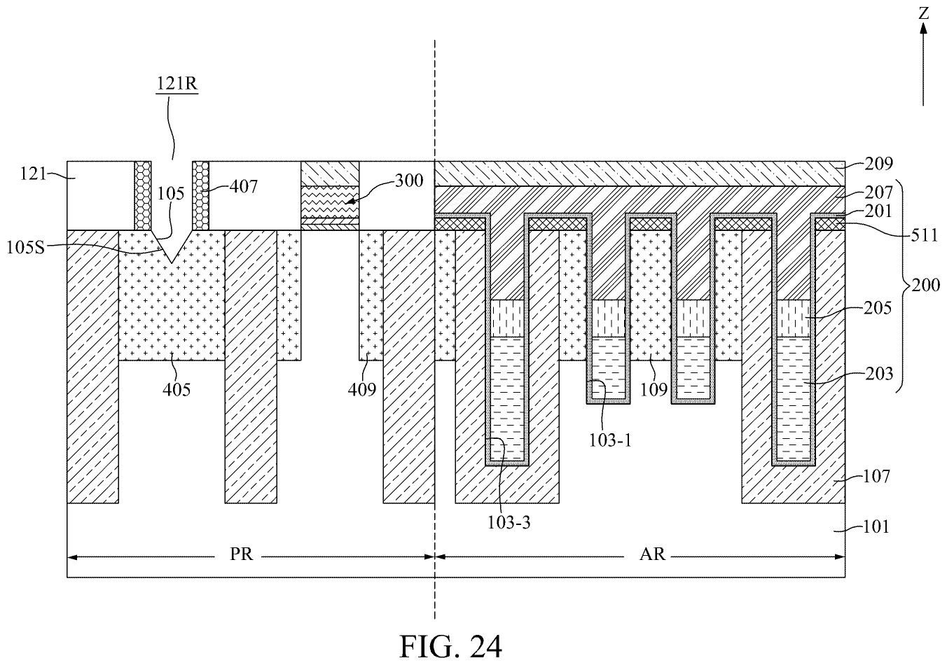

With reference to FIG. 24, in some embodiments, a valley etching process may be performed using an alkaline aqueous based etchant in the recess 121R to remove portions of the peripheral impurity region 405. The alkaline aqueous based etchant may have an etching selectivity to crystal orientation <100> plane. The alkaline aqueous based etchant may include potassium hydroxide, sodium hydroxide, lithium hydroxide, cesium hydroxide, rubidium hydroxide, ammonium hydroxide, or tetramethylammonium hydroxide. After the valley etching process, the valley 105 may be formed extending from the recess 121R and toward the peripheral impurity region 405. In some embodiments, the sidewalls 105S of the valley 105 may have a crystal orientation <111>.

With reference to FIGS. 21, 25, and 26, at step S35, a middle insulating layer 401 may be formed in the recess 121R and the valley 105 and a top electrode layer 403 may be formed on the middle insulating layer 401.

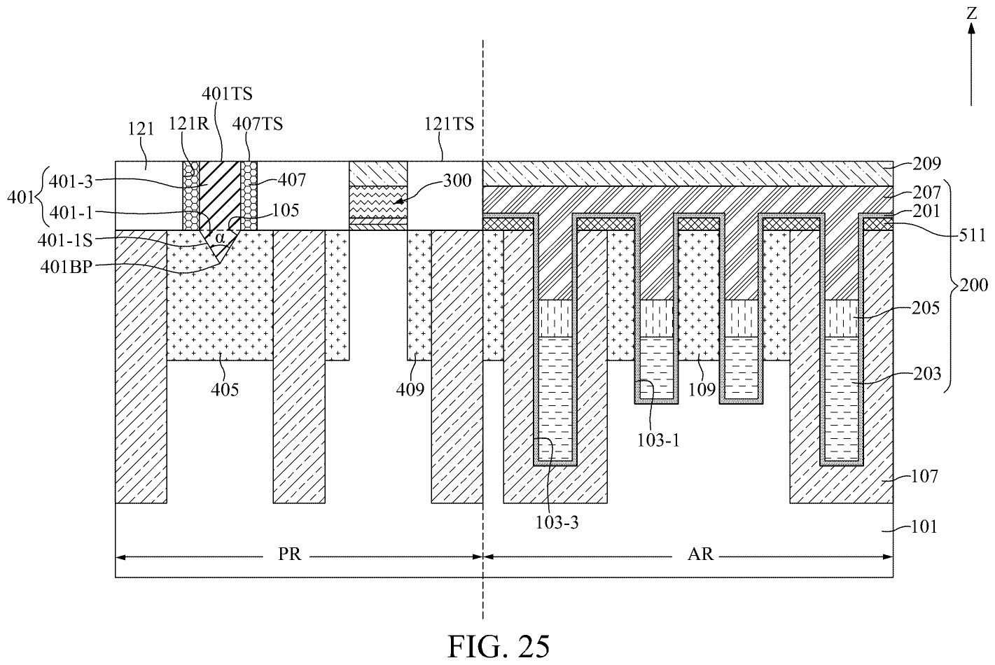

With reference to FIG. 25, the middle insulating layer 401 may be formed filling the recess 121R and the valley 105. In some embodiments, the middle insulating layer 401 may be formed of, for example, oxides, nitrides, oxynitrides, silicates (e.g., metal silicates), aluminates, titanates, nitrides, high-k dielectric materials, or a combination thereof. In some embodiments, the middle insulating layer 401 may be formed by suitable deposition processes, for example, chemical vapor deposition, plasma-enhanced chemical vapor deposition, or other suitable deposition processes. A planarization process, such as chemical mechanical polishing, may be performed until the top surface 121TS of the first inter-dielectric layer 121 is exposed to remove excess material and provide a substantially flat surface for subsequent processing steps. In some embodiments, the top surface 407TS of the plurality of spacers 407, the top surface of the middle insulating layer 401, and the top surface 121TS of the first inter-dielectric layer 121 may be substantially coplanar.

In some embodiments, the middle insulating layer 401 may include a bottom tip portion 401-1 and a top portion 401-3. The bottom tip portion 401-1 may be formed at the valley 105 and surrounded by the peripheral impurity region 405. The top portion 401-3 may be formed at the recess 121R, on the bottom tip portion 401-1, and laterally surrounded by the plurality of spacers 407.

In some embodiments, the bottom tip portion 401-1 of the middle insulating layer 401 may have a triangular profile in a cross-sectional perspective. Two sidewalls 401-1S of the bottom tip portion 401-1 may be tapered and may be jointed at a bottommost point 401BP of the middle insulating layer 401. A width (i.e., a horizontal distance between the sidewalls 401-1S) of the bottom tip portion 401-1 may be gradually decreased along the direction Z toward the substrate 101. An angle α between the sidewalls 401-1S of the bottom tip portion 401-1 may be between about 60 degrees and about 80 degrees or between about 50 degrees and about 70 degrees.

Alternatively, in some other embodiments, the middle insulating layer 401 may be conformally lining the plurality of spacers 407 and the valley 105 (not shown).

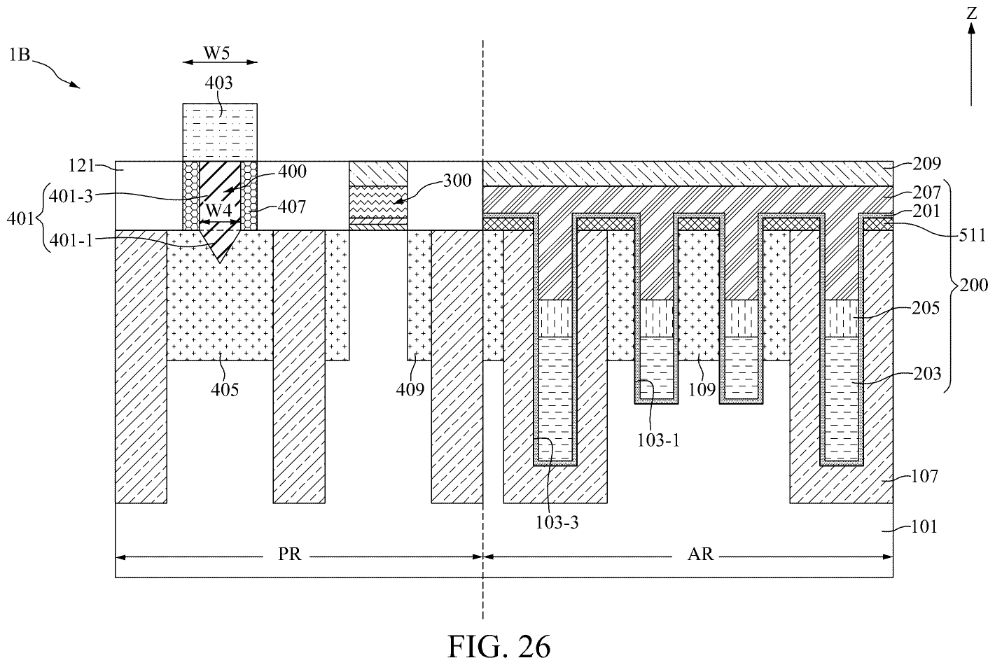

With reference to FIG. 26, the top electrode layer 403 may be formed on the middle insulating layer 401 and the plurality of spacers 407. In some embodiments, the top electrode layer 403 may be formed of, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. In some embodiments, the width W4 of the top portion 401-3 of the middle insulating layer 401 may be less than the width W5 of the top electrode layer 403.

The peripheral impurity region 405, the middle insulating layer 401, and the top electrode layer 403 may together configure a programmable structure 400 such as an anti-fuse.

One aspect of the present disclosure provides a semiconductor device including a substrate; a peripheral impurity region positioned in the substrate; a top electrode layer positioned in the peripheral impurity region and protruding upwardly from the substrate; and a middle insulating layer inwardly positioned in the peripheral impurity region and partially surrounding the top electrode layer to separate the peripheral impurity region and the top electrode layer. The peripheral impurity region, the middle insulating layer, and the top electrode layer together configure a programmable structure.

Another aspect of the present disclosure provides a semiconductor device including a substrate; a peripheral impurity region positioned in the substrate; a middle insulating layer including a bottom tip portion positioned within the peripheral impurity region, and a top portion positioned on the bottom tip portion and above the substrate; and a top electrode layer positioned on the top portion of the middle insulating layer. The peripheral impurity region, the middle insulating layer, and the top electrode layer together configure a programmable structure.

Another aspect of the present disclosure provides a method for fabricating a semiconductor device including providing a substrate and forming a peripheral impurity region in the substrate; forming a first inter-dielectric layer on the substrate; forming a recess penetrating the first inter-dielectric layer and extending to the peripheral impurity region; forming a middle insulating layer on the first inter-dielectric layer and partially filling the recess, resulting in a first opening including a bottom portion and a top portion on the bottom portion; forming a second inter-dielectric layer on the first inter-dielectric layer, filling the top portion of the first opening, and turning the bottom portion of the first opening into a temporary air gap; partially removing the second inter-dielectric layer to forming a second opening including a top portion penetrating the second inter-dielectric layer, a middle portion derived from the top portion of the first opening, and a bottom portion derived from the temporary air gap; and forming a top electrode layer filling the second opening. The peripheral impurity region, the middle insulating layer, and the top electrode layer together configure a programmable structure.

Due to the design of the semiconductor device of the present disclosure, the programmable structure 400 consisting by the peripheral impurity region 405, the middle insulating layer 401, and the top electrode layer 403 may provide an option to change a status of the semiconductor device 1A and an electrical characteristics of the semiconductor device 1A may be changed accordingly. Through tuning the electrical characteristic of the semiconductor device 1A, the quality of the semiconductor device may be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein May be utilized according to the present disclosure. Accordingly, the appended claims are intended to include within their scope such processes, machines, manufacture, compositions of matter, means, methods, and steps.

What is claimed is:

1. A semiconductor device, comprising:
a substrate;
a peripheral impurity region positioned in the substrate;
a middle insulating layer comprising:
a bottom tip portion positioned within the peripheral impurity region; and
a top portion positioned on the bottom tip portion and above the substrate; and
a top electrode layer positioned on the top portion of the middle insulating layer;
wherein the peripheral impurity region, the middle insulating layer, and the top electrode layer together configure a programmable structure.

2. The semiconductor device of claim 1, further comprising a plurality of spacers laterally positioned on the top portion of the middle insulating layer.

3. The semiconductor device of claim 2, wherein a width of the top electrode layer is greater than a width of the middle insulating layer.

4. The semiconductor device of claim 2, wherein the peripheral impurity region comprises n-type dopants or p-type dopants.

5. The semiconductor device of claim 2, wherein a crystal orientation of the substrate is <110>, <100>, or <111>.

6. The semiconductor device of claim 2, wherein the bottom tip portion of the middle insulating layer has a triangular profile in a cross-sectional perspective.

7. The semiconductor device of claim 6, wherein an angle between the two sidewalls of the bottom tip portion of the middle insulating layer is between about 60 degrees and about 80 degrees.

8. The semiconductor device of claim 7, wherein the middle insulating layer comprises oxides, nitrides, oxynitrides, silicates, aluminates, titanates, nitrides, high-k dielectric materials, or a combination thereof.

9. The semiconductor device of claim 7, wherein the top electrode layer comprises tungsten, cobalt, zirconium, tantalum, titanium, aluminum, ruthenium, copper, metal carbides, metal nitrides, transition metal aluminides, or a combination thereof.

10. The semiconductor device of claim 7, further comprising a peripheral gate structure positioned on the substrate and distant from the programmable structure.

11. The semiconductor device of claim 10, wherein the peripheral gate structure comprises:
a gate dielectric layer positioned on the substrate;
a gate bottom conductive layer positioned on the gate dielectric layer;
a gate top conductive layer positioned on the gate bottom conductive layer; and
a top capping layer positioned on the gate top conductive layer.

12. The semiconductor device of claim 11, wherein the substrate comprises an array region and a peripheral region, and the programmable structure and the peripheral gate structure are positioned in the peripheral region.

13. The semiconductor device of claim 12, wherein a top surface of the plurality of spacers and a top surface of the middle insulating layer are substantially coplanar.

14. The semiconductor device of claim 12, further comprising a word line structure positioned in the array region.

15. The semiconductor device of claim 12, wherein the plurality of spacers comprise semiconductor oxides, semiconductor nitrides, semiconductor oxynitrides, or semiconductor carbides.
